(19) United States
(12) Patent Application Publication
(10) Pub. No.: US 2025/0276524 A1
(43) Pub. Date: Sep. 4, 2025

(54) LIQUID EJECTION HEAD

(71) Applicant: SEIKO EPSON CORPORATION, Tokyo (JP)

(72) Inventors: Harunobu KOIKE, MATSUMOTO-SHI (JP); Toshihiro SHIMIZU, FUJIMI-MACHI (JP); Takatoshi YAMAZAKI, SHIOJIRI-SHI (JP)

(21) Appl. No.: 19/069,371

(22) Filed: Mar. 4, 2025

(30) Foreign Application Priority Data
Mar. 4, 2024 (JP) 2024-031938

(51) Int. Cl. B41J 2/14; H10N 30/20

(52) U.S. Cl. CPC B41J 2/14233; H10N 30/2047

(57) ABSTRACT

A liquid ejection head has a piezoelectric element and a vibration plate, and a first electrode, a piezoelectric layer, and a second electrode of the piezoelectric element are laminated in this order in a lamination direction directed from the vibration plate to the piezoelectric element. The first electrode is disposed in a first region and a second region, the first region being a region where the first electrode, the piezoelectric layer, and the second electrode overlap when seen in the lamination direction, the second region being a region where the first electrode overlaps with neither the piezoelectric layer nor the second electrode but overlaps with the vibration plate. A first mixture layer is provided on the first electrode in the second region, the first mixture layer being formed of a mixed material containing lead and a material forming the first electrode.

The present application is based on, and claims priority from JP Application Serial Number 2024-031938, filed Mar. 4, 2024, the disclosure of which are hereby incorporated by reference herein in its entirety.

### BACKGROUND

### 1. Technical Field

The present disclosure relates to a liquid ejection head.

### 2. Related Art

A liquid ejection apparatus, typified by a piezoelectric ink jet printer, uses a liquid ejection head that ejects liquid such as ink. For example, the head described in JP-A-2002-319714 has a vibration plate and a piezoelectric element. The piezoelectric element is formed by a lower electrode, a piezoelectric film, and an upper electrode laminated sequentially on the vibration plate.

In the head described in JP-A-2002-319714, diffusion of lead from the piezoelectric film to the lower electrode may raise electric resistance of the lower electrode and as a result lower the performance of the piezoelectric element.

### SUMMARY

An aspect according to a liquid ejection head of the present disclosure provides a liquid ejection head including: a piezoelectric element having a first electrode, a piezoelectric layer, and a second electrode and a vibration plate, in which the first electrode, the piezoelectric layer, and the second electrode are laminated in this order in a lamination direction which is a direction directed from the vibration plate to the piezoelectric element, the first electrode is disposed in a first region and a second region, the first region being a region where the first electrode, the piezoelectric layer, and the second electrode overlap when seen in the lamination direction, the second region being a region where the first electrode overlaps with neither the piezoelectric layer nor the second electrode but overlaps with the vibration plate, and a first mixture layer is provided on the first electrode in the second region, the first mixture layer being formed of a mixed material containing lead and a material forming the first electrode.

### BRIEF DESCRIPTION OF THE DRAWINGS

FIG. 1 is a configuration diagram schematically showing a liquid ejection apparatus having a liquid ejection head according to an embodiment.

FIG. 2 is an exploded perspective view of the liquid ejection head according to the embodiment.

FIG. 3 is a sectional view taken along the III-III line in FIG. 2.

FIG. 4 is a plan view showing part of the liquid ejection head according to the embodiment.

FIG. 5 is a sectional view taken along the V-V line in FIG. 4.

FIG. 6 is an enlarged view of part VI in FIG. 5.

### DESCRIPTION OF EMBODIMENTS

Preferred embodiments according to the present disclosure are described below with reference to the drawings attached hereto. Note that the dimensions and scales of components in the drawings differ from the actual ones as needed, and some portions are depicted schematically in order to facilitate understanding. Also, the scope of the present disclosure is not limited to those modes of the present disclosure unless the following description specifically states so.

Note that the following description uses an X-axis, a Y-axis, and a Z-axis that are orthogonal to one another, as needed. Also, in the following description, one direction along the X-axis is an X1-direction, and a direction opposite from the X1-direction is an X2-direction. Similarly, directions along the Y-axis that are opposite from each other are a Y1-direction and a Y2-direction. Also, directions along the Z-axis that are opposite from each other are a Z1-direction and a Z2-direction. The Z1-direction is an example of the “lamination direction.” Also, a view seen in a direction along the Z-axis may be referred to as a “plan view”.

The Z-axis is typically a vertical axis, and the Z2-direction corresponds to a vertically downward direction. However, the Z-axis does not have to be a vertical axis. Also, although the X-axis, the Y-axis, and the Z-axis are typically orthogonal to one another, the present disclosure is not limited to this as long as they intersect at an angle in the range of, for example, no less than 80° and no more than 100°.

### 1. Embodiment

### 1-1. Overall Configuration of a Liquid Ejection Apparatus

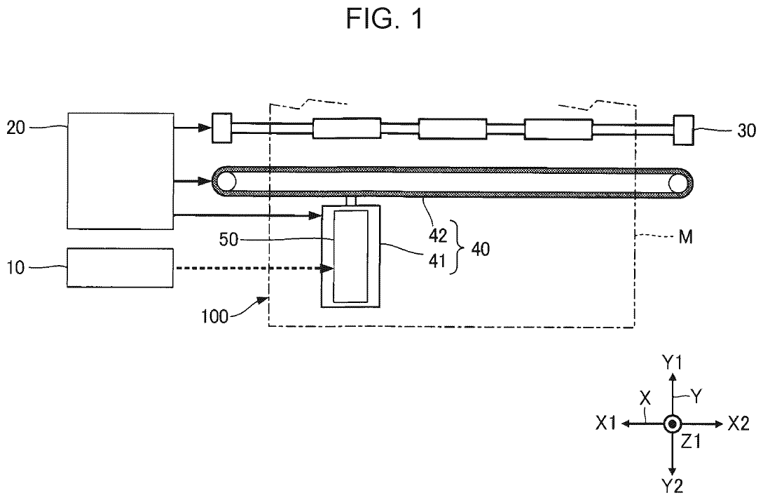

FIG. 1 is a configuration diagram schematically showing a liquid ejection apparatus 100 having a liquid ejection head 50 according to an embodiment. The liquid ejection apparatus 100 is an ink jet printing apparatus that ejects droplets of ink, which is an example of the liquid, to a medium M. The medium M is typically a print sheet. Note that the medium M is not limited to a print sheet, and any material, such as, e.g., a resin film or a cloth, may be used for printing.

As shown in FIG. 1, the liquid ejection apparatus 100 has a liquid container 10, a control unit 20, a conveyance mechanism 30, a movement mechanism 40, and the liquid ejection head 50.

The liquid container 10 is a container storing ink. Example specific modes of the liquid container 10 include a cartridge attachable to and detachable from the liquid ejection apparatus 100, a bag-shaped ink pack formed of a flexible film, and an ink tank that can be replenished with ink. Note that the type of ink stored in the liquid container 10 is not limited to any particular type and may be any type.

The control unit 20 includes, for example, a processing circuit such as a central processing unit (CPU) or a field-programmable gate array (FPGA) and a memory circuit such as semiconductor memory, and controls the operation of each component in the liquid ejection apparatus 100.

As controlled by the control unit 20, the conveyance mechanism 30 conveys the medium M in the Y2-direction. As controlled by the control unit 20, the movement mechanism 40 causes the liquid ejection head 50 to reciprocate in the X1-direction and the X2-direction. In the example shown in FIG. 1, the movement mechanism 40 has a substantially box-shaped carriage 41 housing the liquid ejection head 50 and a conveyor belt 42 to which the carriage 41 is fixed. Note that the number of liquid ejection heads 50 mounted to the carriage 41 is not limited to one and may be more than one. Also, in addition to the liquid ejection head 50, the liquid container 10 described earlier may be mounted to the carriage 41.

As controlled by the control unit 20, the liquid ejection head 50 ejects ink supplied from the liquid container 10 to the medium M in the Z2-direction from each of a plurality of nozzles. This ejection is performed in concurrence with the conveyance of the medium M by the conveyance mechanism 30 and the reciprocating movement of the liquid ejection head 50 by the movement mechanism 40, thereby forming an image on the surface of the medium M with the ink.

### 1-2. Overall Configuration of the Liquid Ejection Head

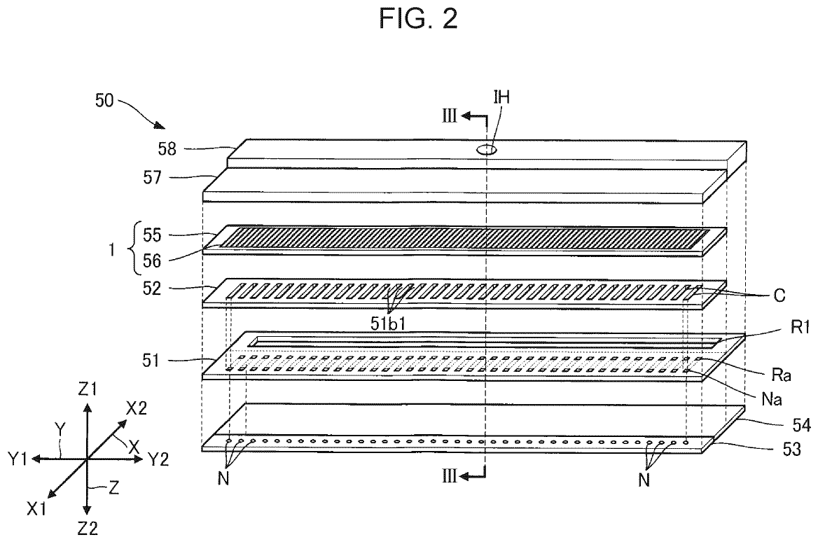

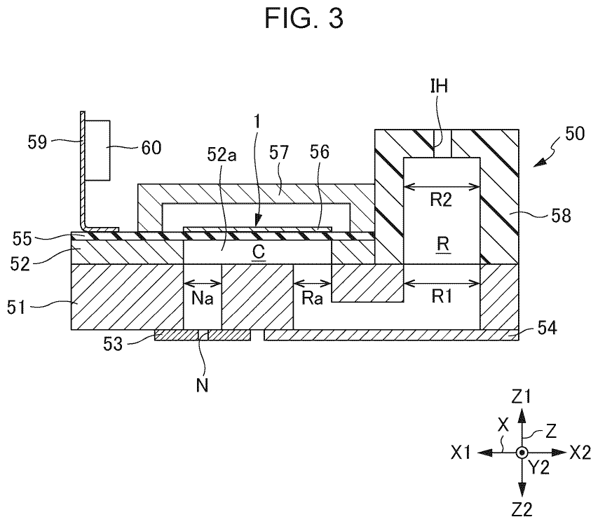

FIG. 2 is an exploded perspective view of the liquid ejection head 50 according to the embodiment. FIG. 3 is a sectional view taken along the III-III line in FIG. 2. As shown in FIGS. 2 and 3, the liquid ejection head 50 has a flow channel substrate 51, a pressure chamber substrate 52, a nozzle plate 53, a vibration absorber 54, a vibration plate 55, a plurality of piezoelectric elements 56, a seal plate 57, a case 58, and a wiring substrate 59. The vibration plate 55 and the piezoelectric element 56 form an actuator 1. In this way, the liquid ejection head 50 has the actuator 1 including the piezoelectric element 56 and the vibration plate 55.

The pressure chamber substrate 52, the vibration plate 55, the plurality of piezoelectric elements 56, the case 58, and the seal plate 57 are disposed in a region located on the Z1-direction side of the flow channel substrate 51. Meanwhile, the nozzle plate 53 and the vibration absorber 54 are disposed in a region located on the Z2-direction side of the flow channel substrate 51. The components of the liquid ejection head 50 are roughly plate members elongated in a direction along the Y-axis and are joined to each other using, for example, an adhesive.

As shown in FIG. 2, the nozzle plate 53 is a plate-shaped member provided with a plurality of nozzles N arrayed in a direction along the Y-axis. Each nozzle N is a through-hole through which ink passes. In this way, the nozzle plate 53 has the plurality of nozzles N that produce jets of ink. The nozzle plate 53 is manufactured by, for example, processing a single-crystal silicon substrate using a semiconductor manufacturing technique employing a processing technique such as dry etching or wet etching. However, other publicly known methods and materials may be used as needed to manufacture the nozzle plate 53.

The flow channel substrate 51 is a plate-shaped member forming flow channels of ink. As shown in FIGS. 2 and 3, the flow channel substrate 51 is provided with an opening portion R1, a plurality of supply flow channels Ra, and a plurality of communication flow channels Na. The opening portion R1 is an elongated through-hole extending in a direction along the Y-axis continuously over the plurality of nozzles N in a plan view seen in a direction along the Z-axis. Meanwhile, the supply flow channels Ra and the communication flow channels Na are through-holes provided for the individual nozzles N. The plurality of supply flow channels Ra each communicate with the opening portion R1. Similarly to the nozzle plate 53 described above, the flow channel substrate 51 is manufactured by, for example, processing a single-crystal silicon substrate using a semiconductor manufacturing technique. However, other publicly known methods and materials may be used as needed to manufacture the flow channel substrate 51.

The pressure chamber substrate 52 is a plate-shaped member where a plurality of pressure chambers C are formed in correspondence to the plurality of nozzles N. The pressure chambers C are spaces called cavities, located between the flow channel substrate 51 and the vibration plate 55 and used to apply pressure to ink filled into the pressure chambers C. The plurality of pressure chambers C are arrayed in a direction along the Y-axis. Each pressure chamber C is formed by a hole 52a opening to both surfaces of the pressure chamber substrate 52 and has an elongated shape extending in a direction along the X-axis. In this way, the pressure chamber substrate 52 has the plurality of pressure chambers C communicating with the nozzles N. Each pressure chamber C, at its end on the X2-direction side, communicates with a corresponding one of the supply flow channels Ra. Meanwhile, each pressure chamber C, at its end on the X1-direction side, communicates with a corresponding one of the communication flow channel Na. Similarly to the nozzle plate 53 described above, the pressure chamber substrate 52 is manufactured by, for example, processing a single-crystal silicon substrate using a semiconductor manufacturing technique. However, other publicly known methods and materials may be used as needed to manufacture the pressure chamber substrate 52.

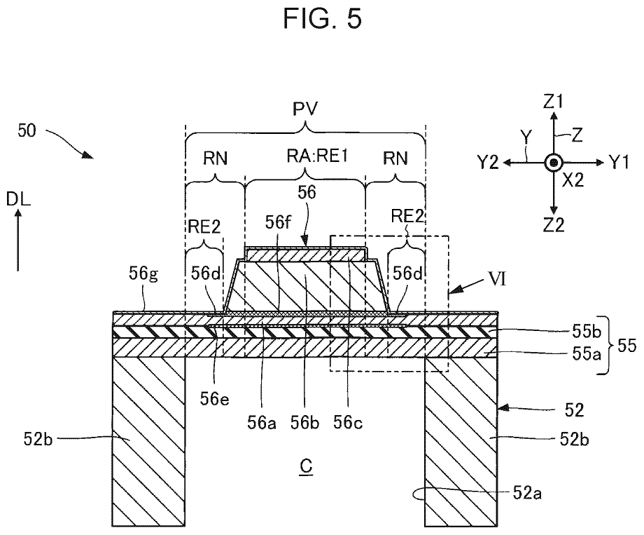

The vibration plate 55 is disposed at the surface of the pressure chamber substrate 52 which faces the Z1-direction. The vibration plate 55 is a plate-shaped member which is elastically deformable and is connected to the piezoelectric elements 56. Note that details of the vibration plate 55 will be described later based on FIG. 5.

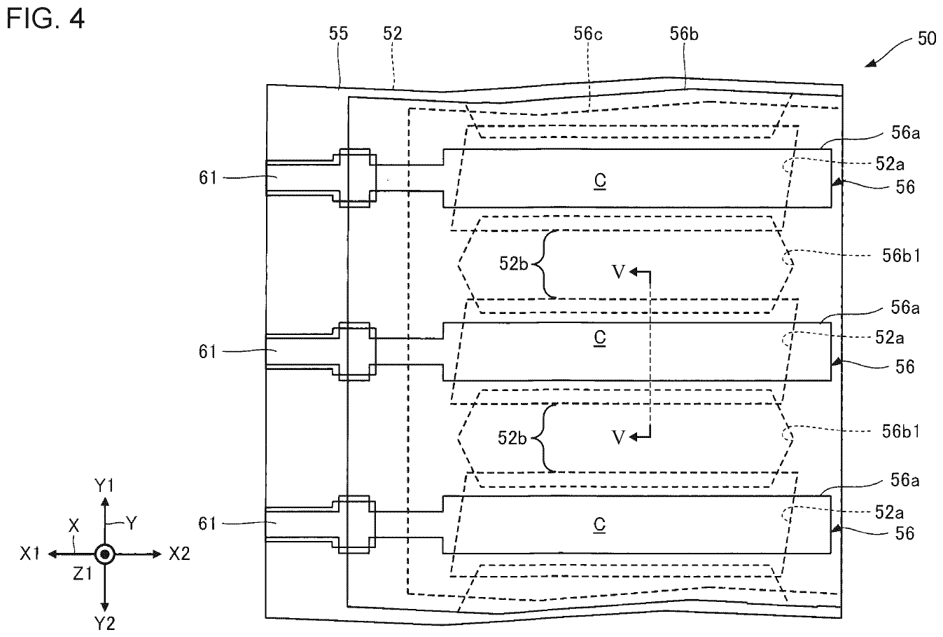

The piezoelectric elements 56 are disposed at the surface of the vibration plate 55 which faces the Z1-direction. Each piezoelectric element 56 is a passive element that deforms upon supply of a drive signal and has an elongated shape extending in a direction along the X-axis. Note that one piezoelectric element 56 is provided for every pressure chamber, and the plurality of piezoelectric elements 56 are arrayed in a direction along the Y-axis in correspondence to the plurality of pressure chambers C. The vibration plate 55 vibrating in conjunction with deformation of the piezoelectric elements 56 fluctuates the pressure inside the pressure chambers C, causing the ink to be ejected from the nozzles N. Note that details of the piezoelectric elements 56 will be described later based on FIGS. 4 to 6.

The case 58 is a case for storing ink to be supplied to the plurality of pressure chambers C and is joined, by means of an adhesive or the like, to the surface of the flow channel substrate 51 which faces the Z1-direction. The case 58 is formed by, for example, a resin material and is manufactured by injection molding. The case 58 is provided with a storage portion R2 and an inlet IH. The storage portion R2 is a concave portion whose outer shape conforms to the opening portion R1 of the flow channel substrate 51. The inlet IH is a through-hole communicating with the storage portion R2. The space formed by the opening portion R1 and the storage portion R2 functions as a liquid storage chamber R as a reservoir for storing ink. Ink from the liquid container 10 is supplied to the liquid storage chamber R through the inlet IH.

The vibration absorber 54 is a component for absorbing fluctuations in the pressure inside the liquid storage chamber R. The vibration absorber 54 is, for example, a compliance substrate which is a flexible, elastically deformable sheet member. The vibration absorber 54 is disposed at the surface of the flow channel substrate 51 which faces the Z2-direction, closing the opening portion R1 and the plurality of supply flow channels Ra of the flow channel substrate 51 to form the bottom surface of the liquid storage chamber R.

The seal plate 57 is a structure that not only protects the plurality of piezoelectric elements 56 but also reinforces the mechanical strength of the pressure chamber substrate 52 and the vibration plate 55. The seal plate 57 is joined to a surface of the vibration plate 55 using, for example, an adhesive. The seal plate 57 is provided with a concave portion for housing the plurality of piezoelectric elements 56.

The wiring substrate 59 is joined to the surface of the pressure chamber substrate 52 or the vibration plate 55 which faces the Z1-direction. The wiring substrate 59 is a mount component where a plurality of interconnections are formed to electrically connect the control unit 20 and the liquid ejection head 50. The wiring substrate 59 is, for example, a flexible wiring substrate such as a flexible printed circuit (FPC) or a flexible flat cable (FFC). A drive circuit 60 for driving the piezoelectric elements 56 is mounted on the wiring substrate 59. The drive circuit 60 selectively supplies each piezoelectric element 56 with a drive signal for driving the piezoelectric element 56 via the wiring substrate 59.

### 1-3. Details of the Vibration Plate and the Piezoelectric Elements

FIG. 4 is a plan view showing part of the liquid ejection head 50 according to the embodiment. FIG. 5 is a sectional view taken along the V-V line in FIG. 4. Based on FIGS. 4 and 5, the following describes the pressure chamber substrate 52, the piezoelectric element 56, and the vibration plate 55 in this order.

As shown in FIGS. 4 and 5, the pressure chamber substrate 52 is provided with the holes 52a forming the pressure chambers C. The pressure chamber substrate 52 is accordingly provided with a wall-shaped partitioning wall 52b between each pair of adjacent holes 52a, the partitioning wall 52b extending in a direction along the X-axis. The pressure chamber substrate 52 is manufactured by, for example, processing a single-crystal silicon substrate using a semiconductor manufacturing technique. FIG. 4 shows, using broken lines, the plan-view shapes of the holes 52a formed in a substrate of single-crystal silicon with a (110) plane orientation using anisotropic etching. Note that the plan-view shapes of the hole 52a are not limited to the example shown in FIG. 4 and may be any shape.

The pressure chambers C are formed after the formation of the piezoelectric elements 56. The pressure chambers C are formed by, for example, performing anisotropic etching on one of the surfaces of the single-crystal silicon substrate having the piezoelectric element 56 already formed therein, the one surface being opposite from the surface where the piezoelectric elements 56 are formed. In this anisotropic etching, for example, a potassium hydroxide (KOH) solution or the like is used as an etching liquid. Also, in a case where an elastic layer 55a is formed of silicon oxide, the elastic layer 55a functions as a stop layer for stopping the anisotropic etching. After the formation of the pressure chambers C, the flow channel substrate 51 and the like are joined to the pressure chamber substrate 52 with, for example, an adhesive. Note that after the formation of the piezoelectric element 56, the surface of the single-crystal silicon substrate opposite from the surface where the piezoelectric elements 56 are formed is polished by chemical mechanical polishing (CMP) or the like as needed to flatten the surface and adjust the thickness of the substrate.

As shown in FIG. 4, the piezoelectric elements 56 overlap with the pressure chambers C in a plan view. As shown in FIG. 5, the piezoelectric element 56 has a first electrode 56a, a piezoelectric layer 56b, and a second electrode 56c, and they are laminated in this order in the Z1-direction. Specifically, the first electrode 56a, the piezoelectric layer 56b, and the second electrode 56c are laminated in this order in a lamination direction DL, which is a direction directed from the vibration plate 55 to the piezoelectric element 56. Also, the piezoelectric element 56 has, in addition to the first electrode 56a, the piezoelectric layer 56b, and the second electrode 56c, a first mixture layer 56d, a second mixture layer 56e, a third mixture layer 56f, and a protection layer 56g.

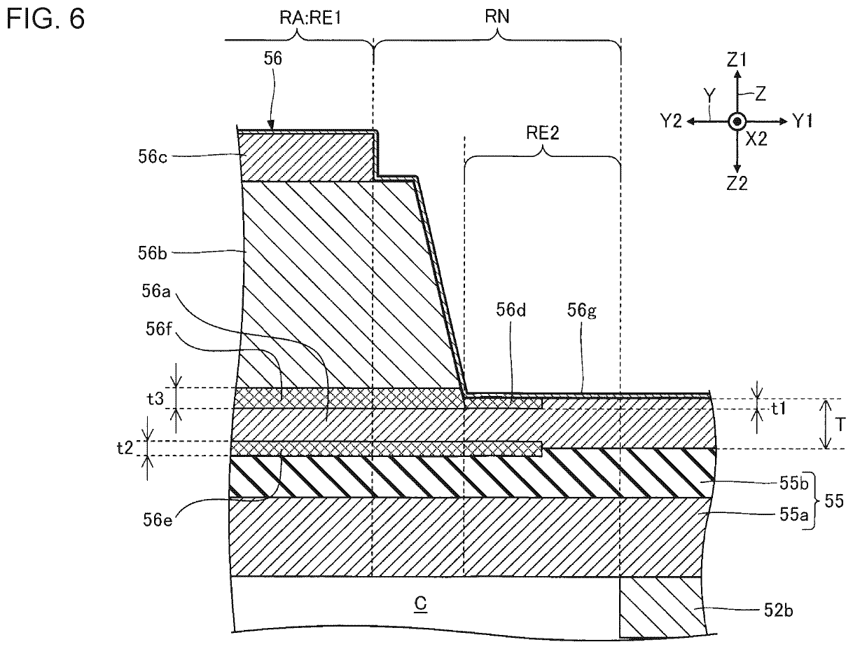

Based on FIGS. 4 and 5, the following describes the first electrode 56a, the piezoelectric layer 56b, and the second electrode 56c in this order. Note that the first mixture layer 56d, the second mixture layer 56e, the third mixture layer 56f, and the protection layer 56g will be described later based on FIG. 6.

The first electrode 56a is a belt-shaped common electrode extending in a direction along the Y-axis continuously over the plurality of piezoelectric elements 56. The first electrode 56a is supplied with a predetermined constant potential.

The first electrode layer 56a has, for example, a layer formed of platinum (Pt), a layer formed of iridium (Ir), and a layer formed of titanium (Ti). In other words, the electrode layer 56a1 contains platinum, iridium, and titanium. Platinum is an electrode material having good conductivity. Thus, using platinum as a material forming the first electrode 56a can lower the resistance of the first electrode 56a. Also, in formation of the piezoelectric layer 56b, the layer formed of titanium and island-shaped titanium acts as a crystal nucleus and controls the orientation of the piezoelectric layer 56b, enhancing the crystallinity and orientation of the piezoelectric layer 56b. Note that in place of or in addition of these layers, a layer formed of a different metal material or conductive oxide may be provided. Also, such a layer may have a layer of a mixture of a plurality of metal materials or a layer formed of an alloy.

For example, the first electrode 56a is formed after the formation of the vibration plate 55, using a publicly known film formation technique such as sputtering and publicly known processing techniques such as photolithography and etching. Also, the thickness of the first electrode 56a is, for example, approximately 100 nm.

In the example shown in FIGS. 4 and 5, the piezoelectric layer 56b has a belt shape extending in a direction along the Y-axis continuously over the plurality of piezoelectric elements 56. In the example shown in FIG. 4, in regions corresponding to the gaps between the adjacent pressure chambers C in a plan view, the piezoelectric layer 56b is provided with through-holes 56b1 penetrating through the piezoelectric layer 56b and extending in a direction along the X-axis. Thus, in a sectional view shown in FIG. 5, the piezoelectric layer 56b is provided individually for each piezoelectric element 56. Note that the piezoelectric layer 56b may be provided individually for the plurality of piezoelectric elements 56.

The piezoelectric layer 56b is formed of a piezoelectric material containing lead as a constituent element. The piezoelectric material has a perovskite crystal structure expressed by a general composition formula ABO₃ and is, for example, lead zirconate titanate (Pb(Zr, Ti)O₃). Also, in addition to lead (Pb), the piezoelectric layer 56b may contain at least one element selected from vanadium (V), niobium (Nb), tantalum (Ta), nickel (Ni), phosphorus (P), arsenic (As), antimony (Sb), and bismuth (Bi). Note that lead contained in the piezoelectric material constituting the piezoelectric layer 56b may be an element that does not constitute part of the perovskite crystal structure.

For example, the piezoelectric layer 56b is formed after the formation of the first electrode 56a, by forming a uniform piezoelectric precursor layer through a sol-gel process, baking and crystalizing the precursor layer, and then performing patterning by etching such as reactive ion etching (RIE) or ion milling.

The second electrodes 56c are individual electrodes disposed for the respective piezoelectric elements 56 and spaced away from one another. Specifically, a plurality of second electrodes 56c extending in a direction along the X-axis are arrayed in a direction along the Y-axis with spaces in between. The second electrode 56c of each piezoelectric element 56 is supplied with a drive signal including a predetermined voltage pulse from the control unit 20.

The second electrode 56c is formed of, for example, platinum (Pt). Note that the material forming the second electrode 56c is not limited to platinum, and may be, for example, a metal material such as titanium (Ti), iridium (Ir), aluminum (Al), nickel (Ni), gold (Au), or copper (Cu) or a conductive oxide such as lanthanum nickel oxide (LaNiO₃:LNO) or strontium ruthenium oxide (SrRuO₃:SRO). Also, the second electrode 56c may use a single one of these metal materials or may combine two or more of them using a mode such as lamination.

For example, the second electrode 56c is formed after the formation of the piezoelectric layer 56b, using a publicly known film formation technique such as sputtering and publicly known processing techniques such as photolithography and etching. Also, the thickness of the second electrode 56c is, for example, approximately 150 nm.

In the piezoelectric element 56 thus described, upon application of a voltage between the first electrode 56a and the second electrode 56c, the piezoelectric layer 56b deforms due to the inverse piezoelectric effect. The vibration plate 55 is connected to the piezoelectric element 56 and vibrates as the piezoelectric layer 56b deforms.

As shown in FIG. 5, the vibration plate 55 has the elastic layer 55a and an insulating layer 55b, which are laminated in this order in the Z1-direction. The insulating layer 55b is disposed offset to a position closer to the first electrode 56a in the direction of the thickness of the vibration plate 55.

The elastic layer 55a is a film formed of, for example, silicon oxide (SiO₂). Note that a material forming the elastic layer 55a is not limited to SiO₂, and may be, for example, a material containing one element or two or more elements selected from titanium (Ti), silicon (Si), aluminum (Al), tantalum (Ta), chromium (Cr), iridium (Ir), hafnium (Hf), zirconium (Zr), and carbon (C), in an elemental form, an oxide form, or a nitride form.

The thickness of the elastic layer 55a is determined based on, e.g., the thickness and width of the vibration plate 55 and not limited to any particular thickness, but is, for example, in the range of no less than 100 nm and no more than 3000 nm.

The insulating layer 55b is a film formed of, for example, zirconium oxide (ZrO₂) and contains zirconium (Zr). The insulating layer 55b thus containing zirconium is disposed offset to a position closer to the first electrode 56a in the thickness direction of the vibration plate 55, which enables the insulating layer 55b to inhibit diffusion of lead from the first electrode 56a to the elastic layer 55a. Note that the material forming the insulating layer 55b is not limited to ZrO₂ and may be, for example, a material containing one element or two or more elements selected from titanium (Ti), aluminum (Al), tantalum (Ta), chromium (Cr), hafnium (Hf), zirconium (Zr), and silicon (Si), in an oxide or nitride form.

The thickness of the insulating layer 55b is determined based on, e.g., the thickness and width of the vibration plate 55 and not limited to any particular thickness, but is, for example, in the range of no less than 100 nm and no more than 2000 nm.

In the example shown in FIG. 5, the elastic layer 55a and the insulating layer 55b are in contact with each other. Note that another layer may be interposed between the elastic layer 55a and the insulating layer 55b, such as an adhesion layer for enhancing the adhesion between the elastic layer 55a and the insulating layer 55b. A material forming the adhesion layer is, for example, TiO_{X}, AlO_{X}, CrO_{X}, or TiN. The thickness of the adhesion layer is determined based on the thickness and width of the vibration plate 55 and not limited to any particular thickness, but is, for example, in the range of no less than 20 nm and no more than 2000 nm.

The elastic layer 55a and the insulating layer 55b thus described are formed as films in this order on the single-crystal silicon substrate for forming the pressure chamber substrate 52. For example, in a case where the elastic layer 55a is formed of silicon oxide, the elastic layer 55a is formed by thermal oxidization of one of the surfaces of the single-crystal silicon substrate. For example, in a case where the insulating layer 55b is formed of zirconium oxide, the insulating layer 55b is formed by thermal oxidization of a zirconium layer formed by sputtering on the elastic layer 55a.

Note that methods for forming the plurality of films forming the vibration plate 55 are not limited to the examples described above, and any methods may be used. For example, chemical vapor deposition (CVD) or the like may be used to form at least part of the elastic layer 55a. Also, in a case where an adhesion layer is provided between the elastic layer 55a and the insulating layer 55b, the adhesion layer is formed by thermal oxidation of a layer of chromium, titanium, aluminum, or the like formed by sputtering on the elastic layer 55a. The thermal oxidation for forming the adhesive layer may be performed concurrently with the thermal oxidation for forming the insulating layer 55b. Also, the formation of the adhesive layer is not limited to the method using thermal oxidation and may be performed using, for example, CVD, atomic layer deposition (ALD), or the like.

The actuator 1 formed by the vibration plate 55 and the piezoelectric element 56 thus described has a vibration region PV that vibrates when the piezoelectric element 56 is driven. The vibration region PV is part of the actuator 1 and is a portion overlapping with the pressure chamber C in a plan view.

The vibration region PV is divided into an active portion RA and a non-active portion RN. The active portion RA is part of the actuator 1 and is a region overlapping with the pressure chamber C, the first electrode 56a, the piezoelectric layer 56b, and the second electrode 56c when seen in a direction along the Z-axis. The non-active portion RN is part of the actuator 1 and is a portion overlapping with the pressure chamber C when seen in a direction along the Z-axis and being different from the active portion RA.

Hereinbelow, a region corresponding to the active portion RA when seen in a direction along the Z-axis is referred to as a first region RE1. In other words, the first region RE1 is a region overlapping with the first electrode 56a, the piezoelectric layer 56b, and the second electrode 56c when seen in the lamination direction DL. Also, a region where the first electrode 56a overlaps with neither the piezoelectric layer 56b nor the second electrode 56c but overlaps with the vibration plate 55 when seen in the lamination direction DL is referred to as a second region RE2. The second region RE2 is encompassed by the region corresponding to the non-active portion RN when seen in a direction along the Z-axis. Being a common electrode as described earlier, the first electrode 56a is disposed in the first region RE1 and the second region RE2.

FIG. 6 is an enlarged view of part VI in FIG. 5. As shown in FIG. 6, the piezoelectric element 56 has the first mixture layer 56d, the second mixture layer 56e, the third mixture layer 56f, and the protection layer 56g in addition to the first electrode 56a, the piezoelectric layer 56b, and the second electrode 56c described above.

The first mixture layer 56d is a layer which is provided on the first electrode 56a in the second region RE2 and which is formed of a mixed material containing lead and a material forming the first electrode 56a. In the example shown in FIG. 6, the first mixture layer 56d is provided in the second region RE2. Specifically, the first mixture layer 56d is provided in part of the second region RE2, with the first region RE1 side of the first mixture layer 56d coinciding with the first region RE1 side of the second region RE2. Note that, for illustrative convenience, FIG. 6 distinctly depicts the interface between the first mixture layer 56d and the first electrode 56a, but the interface does not have to be distinct and may be such that the mixture ratio of the mixed material gradually changes in the thickness direction. Also, the first mixture layer 56d may be provided over the entire second region RE2 or also at positions overlapping with the partitioning walls 52b in a plan view.

When the first mixture layer 56d contains lead, compared to when the first mixture layer 56d does not contain lead, it makes it difficult for lead in the piezoelectric layer 56b to diffuse to the first electrode 56a located in the second region RE2 or on the Y1 direction side of the second region RE2. Thus, the provision of the first mixture layer 56d on the first electrode 56a in the second region RE2 can inhibit diffusion of lead from the un-patterned piezoelectric layer 56b to the first electrode 56a in the second region RE2 in the formation of the piezoelectric layer 56b. Also, diffusion of lead from the widthwise end of the patterned piezoelectric layer 56b toward the first electrode 56a in the second region RE2 can be inhibited. Diffusion of lead from the piezoelectric layer 56b to the first electrode 56a is favorably prevented especially when the first region RE1 side of the first mixture layer 56d coincides with the first region RE1 side of the second region RE2.

The mixed material forming the first mixture layer 56d contains, for example, lead and the material forming the first electrode 56a, which is at least one of platinum, iridium (Ir), and titanium (Ti), in an alloyed, oxide, nitride, or oxynitride form. Although there is no particular limitation, for example, the first mixture layer 56d is formed after the formation of the first electrode 56a, using a film formation technique such as ion plating. Note that the mixed material forming the first mixture layer 56d may contain an element other than the material forming the first electrode 56a.

The first mixture layer 56d contains a constituent element of the material forming the third mixture layer 56f functioning as an adhesion layer as will be described later. This enables a compound of lead and the material forming the third mixture layer 56f to be formed in the first mixture layer 56d. This as a result can inhibit diffusion of lead from the piezoelectric layer 56b to the first electrode 56a in the first region RE1 more favorably.

It is preferable that the constituent element of the material forming the third mixture layer 56f functioning as an adhesion layer as will be described later be contained in the first mixture layer 56d in an oxidized state. In other words, the first mixture layer 56d preferably contains oxide of the constituent element of the material forming the third mixture layer 56f. This can inhibit oxygen loss from the piezoelectric layer 56b to the first mixture layer 56d.

When the third mixture layer 56f contains titanium or titanium oxide and the first mixture layer 56d contains titanium or titanium oxide, the content of titanium and titanium oxide in the first mixture layer 56d in the second region RE2 is preferably higher than the content of titanium and titanium oxide in the third mixture layer 56f in the first region RE1. Further, it is more preferable when the titanium oxide content percentage in the first mixture layer 56d in the second region RE2 is higher than the titanium oxide content percentage in the third mixture layer 56f in the first region RE1. This can favorably inhibit oxygen loss from the piezoelectric layer 56b to the first mixture layer 56d.

The contents of titanium and titanium oxide in the first mixture layer 56d and the third mixture layer 56f are calculated by, for example, measuring a lead content and an oxygen content in each of the first mixture layer 56d and the third mixture layer 56f over a region of an area of 1 mm² in a plan view at measurement time intervals by use of secondary ion mass spectrometry and standardizing the titanium content by the oxygen content.

The lead content percentage in the first mixture layer 56d is preferably higher than the lead content percentage in the first electrode 56a in the second region RE2. Also, the lead content percentage in the first mixture layer 56d is preferably higher than the lead content percentage in the piezoelectric layer 56b. The lead content percentages are calculated by, for example, measuring a lead content and an oxygen content over a region of an area of 1 mm² in a plan view at measurement time intervals by use of secondary ion mass spectrometry and standardizing the titanium content by the oxygen content. The lead content percentage in the first mixture layer 56d is preferably in the range of no less than 30 atm % and no more than 70 atm % and more preferably in the range of no less than 40 atm % and no more than 60 atm %. Note that the lead content percentages may be measured using a different method such as energy dispersive X-ray analysis.

A thickness t1 of the first mixture layer 56d is preferably no less than 1/2000 and no more than ½ a thickness T of the first electrode 56a. This can not only inhibit diffusion of lead to the first electrode 56a in the second region RE2, but also suppress a rise in the electrical resistance of the first electrode 56a attributable to the first mixture layer 56d.

The thickness t1 of the first mixture layer 56d is, for example, in the range of no less than 0.1 nm and no more than 50 nm. The first mixture layer 56d may be a closely packed layer or may be a sparse layer where the above-described mixed material is scattered in the shapes of island.

The second mixture layer 56e is provided between the first electrode 56a and the vibration plate 55 in the second region RE2 and is formed of a mixed material containing lead and the material forming the first electrode 56a. This can improve the adhesion between the vibration plate 55 and the first electrode 56a. In the example shown in FIG. 6, the second mixture layer 56e is provided between the first electrode 56a and the vibration plate 55 not only in the second region RE2 but also in the first region RE1. In other words, the second mixture layer 56e is provided between the first electrode 56a and the vibration plate 55 in the first region RE1 and the second region RE2. Also, the end of the second mixture layer 56e in the Y-axis direction is located in the second region RE2. Note that, for illustrative convenience, FIG. 6 distinctly depicts the interface between the second mixture layer 56e and the first electrode 56a and the interface between the second mixture layer 56e and the insulating layer 55b, but these interfaces do not have to be distinct and may be such that, for example, the mixture ratio of the mixed material gradually changes in the thickness direction. Also, the end of the second mixture layer 56e in the Y-axis direction may coincide with the end of the second region RE2 which is opposite from the first region RE1 side or may overlap with the partitioning wall 52b in a plan view. Further, the portion of the second mixture layer 56e in the first region RE1 is provided as needed and may be omitted.

Similarly to the first mixture layer 56d, the mixed material forming the second mixture layer 56e contains, for example, lead and the material forming the first electrode 56a, which is at least one of platinum (Pt), iridium (Ir), and titanium (Ti), in an alloyed, oxide, nitride, or oxynitride form. Although there is no particular limitation, for example, the second mixture layer 56e is formed after the formation of the vibration plate 55, using a film formation technique such as ion plating. Note that the mixed material forming the second mixture layer 56e may contain an element other than the material forming the first electrode 56a.

A thickness t2 of the second mixture layer 56e is preferably thicker than the thickness t1 of the first mixture layer 56d. In other words, the thickness t1 of the first mixture layer 56d is preferably thinner than the thickness t2 of the second mixture layer 56e. The first mixture layer 56d and the second mixture layer 56e contain lead. A larger lead content increases electrical resistance in the layer and lowers the voltage exerted to the piezoelectric layer 56b. In the present configuration, the first mixture layer 56d provided on the piezoelectric layer 56b side is thinner than the second mixture layer 56e; thus, the electrical resistance can be lowered in the portion of the first electrode 56a which is on the piezoelectric layer 56b side. This as a result can suppress a drop in the voltage applied to the piezoelectric layer 56b between the first electrode 56a and the second electrode 56c.

In the first region RE1, the first electrode 56a has a layer formed of metal such as platinum between the third mixture layer 56f and the second mixture layer 56e; thus, it is not problematic even if the second mixture layer 56e is somewhat thick. Also, because the second mixture layer 56e is disposed at the opposite side of the first electrode 56a from the piezoelectric layer 56b, the voltage applied to the piezoelectric layer 56b between the first electrode 56a and the second electrode 56c is not likely to drop despite the presence of the second mixture layer 56e.

The thickness t2 of the second mixture layer 56e is, for example, in the range of no less than 1 nm and no more than 100 nm. The second mixture layer 56e may be a closely packed layer or may be a sparse layer where the above-described mixed material is scattered in the shapes of island.

The third mixture layer 56f is provided on the first electrode 56a in the first region RE1 and is formed of a mixed material containing lead and the material forming the first electrode 56a. This can improve the adhesion between the piezoelectric layer 56b and the first electrode 56a. Note that, for illustrative convenience, FIG. 6 distinctly depicts the interface between the third mixture layer 56f and the first electrode 56a and the interface between the third mixture layer 56f and the piezoelectric layer 56b, but these interfaces do not have to be distinct and may be such that, for example, the mixture ratio of the mixed material gradually changes in the thickness direction.

Similarly to the first mixture layer 56d, the mixed material forming the third mixture layer 56f contains, for example, lead and at least one of platinum (Pt), iridium (Ir), and titanium (Ti), in an alloyed, oxide, nitride, or oxynitride form. By containing Ti (titanium), the third mixture layer 56f in particular functions as an adhesion layer as well. Although there is no particular limitation, for example, the third mixture layer 56f is formed after the formation of the first electrode 56a, using a film formation technique such as ion plating. Note that the mixed material forming the third mixture layer 56f may contain an element other than the material forming the first electrode 56a.

A thickness t3 of the third mixture layer 56f is preferably thicker than the thickness t1 of the first mixture layer 56d. In other words, the thickness t1 of the first mixture layer 56d is preferably thinner than the thickness t3 of the third mixture layer 56f. This can suppress a rise in the electrical resistance of the first electrode 56a in the second region RE2.

The thickness t3 of the third mixture layer 56f is, for example, in the range of no less than 0.2 nm and no more than 100 nm. The third mixture layer 56f may be a closely packed layer or may be a sparse layer where the above-described mixed material is scattered in the shapes of island.

The protection layer 56g is a layer covering a laminate formed by the first electrode 56a, the piezoelectric layer 56b, and the second electrode 56c from above and protects the laminate. For example, the protection layer 56g is formed of metal oxide such as Al₂O₃, TaO_{X}, IrO_{X}, or TiO_{X}. Although there is no particular limitation, for example, the protection layer 56g is formed after the formation of the laminate, using a film formation technique such as chemical vapor deposition (CVD).

The portion of the protection layer 56g which is provided on the first mixture layer 56d in the lamination direction DL functions as a lead diffusion inhibition layer that inhibits diffusion of lead. This can inhibit diffusion of lead from above the first mixture layer 56d to the first electrode 56a.

The thickness of the protection layer 56g is not limited to any particular thickness, but is, for example, in the range of no less than 20 nm and no more than 50 nm.

### 2. Modifications

The modes exemplified above can be variously modified. Specific modifications that may be applied to the above-described modes are exemplified below. Note that any of two or more modes selected from the following examples may be combined as needed without conflicting with each other.

### 2-1. Modification 1

Although the second mixture layer 56e, the third mixture layer 56f, and the protection layer 56g are used in the example mode described in the above embodiment, the present disclosure is not limited to this mode, and at least one of the second mixture layer 56e, the third mixture layer 56f, and the protection layer 56g may be omitted.

### 2-2. Modification 2

In the modes described above, the piezoelectric layer 56b is provided commonly for the plurality of pressure chambers C; however, the present disclosure is not limited to this, and the piezoelectric layer 56b may be divided for the pressure chambers C.

### 2-3. Modification 3

In the modes described above, the serial-type liquid ejection apparatus 100 in which the carriage 41 having the liquid ejection head 50 mounted thereto reciprocates is used as an example; however, the present disclosure can also be applied to a line-type liquid ejection apparatus in which the plurality of nozzles N are distributed over the entire width of the medium M.

### 2-4. Modification 4

The liquid ejection apparatus 100 exemplified in the above modes may be employed not only for a device dedicated for printing, but also various other devices such as a facsimile device or a copier device. However, the purpose of the liquid ejection apparatus of the present disclosure is not limited to printing. For example, a liquid ejection apparatus that ejects a solution of a color material may be used as a manufacturing apparatus that produces color filters for liquid crystal display devices. Also, a liquid ejection apparatus that ejects a solution of a conductive material may be used as a manufacturing apparatus that produces wiring and electrodes on wiring boards.

### 3. The Overview of the Present Disclosure

The following supplementarily provides the overview of the present disclosure.

(Supplemental Note 1) A first mode as a preferred example of a liquid ejection head of the present disclosure has: a piezoelectric element having a first electrode, a piezoelectric layer, and a second electrode and a vibration plate connected to the piezoelectric element. The first electrode, the piezoelectric layer, and the second electrode are laminated in this order in a lamination direction which is a direction directed from the vibration plate to the piezoelectric element. The first electrode is disposed in a first region and a second region, the first region being a region where the first electrode, the piezoelectric layer, and the second electrode overlap when seen in the lamination direction, the second region being a region where the first electrode overlaps with neither the piezoelectric layer nor the second electrode but overlaps with the vibration plate. A first mixture layer is provided on the first electrode in the second region, the first mixture layer being formed of a mixed material containing lead and a material forming the first electrode.

In the above mode, the provision of the first mixture layer on the first electrode in the second region can inhibit diffusion of lead from the un-patterned piezoelectric layer to the first electrode in the second region in the formation of the piezoelectric layer. It is also possible to inhibit diffusion of lead from the widthwise end of the patterned piezoelectric layer toward the first electrode in the second region or outward of the second region.

(Supplementary Note 2) A second mode as a preferred example of the first mode further has an adhesion layer disposed between the first electrode and the piezoelectric layer in the lamination direction, and the first mixture layer contains a constituent element of a material forming the adhesion layer. In the above mode, a compound of lead and the material forming the adhesion layer can be formed in the first mixture layer. This as a result can inhibit diffusion of lead from the piezoelectric layer to the first electrode in the first region more favorably.

(Supplementary Note 3) In a third mode as a preferred example of the second mode, the first mixture layer contains oxide of the constituent element of the material forming the adhesion layer. The above mode can inhibit oxygen loss from the piezoelectric layer to the first mixture layer.

(Supplementary Note 4) In a fourth mode as a preferred example of any one of the first to third modes, a lead diffusion inhibition layer that inhibits diffusion of lead is provided on the first mixture layer in the lamination direction. The above mode can inhibit diffusion of lead from above the first mixture layer to the first electrode.

(Supplementary Note 5) In a fifth mode as a preferred example of any one of the first to fourth modes, a second mixture layer is provided between the first electrode and the vibration plate in the second region, the second mixture layer being formed of a mixed material containing lead and the material forming the first electrode. The above mode can improve the adhesion between the vibration plate and the first electrode.

(Supplementary Note 6) In a sixth mode as a preferred example of the fifth mode, thickness of the first mixture layer is thinner than thickness of the second mixture layer. The above mode can lower the electric resistance of the portion of the first electrode which is at the piezoelectric layer side. This as a result can suppress a drop in the voltage applied to the piezoelectric layer between the first electrode and the second electrode.

(Supplementary Note 7) In a seventh mode as a preferred example of any one of the first to sixth modes, a third mixture layer is provided on the first electrode in the first region, the third mixture layer being formed of a mixed material containing lead and the material forming the first electrode, and thickness of the first mixture layer is thinner than thickness of the third mixture layer. In the above mode, the provision of the third mixture layer on the first electrode in the first region can improve the adhesion between the piezoelectric layer and the first electrode. Also, the thickness of the first mixture layer being thinner than the thickness of the third mixture layer can suppress a rise in the electrical resistance of the first electrode in the second region.

(Supplementary Note 8) In an eighth mode as a preferred example of any one of the first to seventh modes, thickness of the first mixture layer is no less than 1/2000 and no more than ½ of thickness of the first electrode. The above mode can not only inhibit diffusion of lead to the first electrode in the second region, but also suppress a rise in the electrical resistance of the first electrode attributable to the first mixture layer.

What is claimed is:

1. A liquid ejection head comprising:
a piezoelectric element having a first electrode, a piezoelectric layer, and a second electrode and
a vibration plate, wherein
the first electrode, the piezoelectric layer, and the second electrode are laminated in this order in a lamination direction which is a direction directed from the vibration plate to the piezoelectric element,
the first electrode is disposed in a first region and a second region, the first region being a region where the first electrode, the piezoelectric layer, and the second electrode overlap when seen in the lamination direction, the second region being a region where the first electrode overlaps with neither the piezoelectric layer nor the second electrode but overlaps with the vibration plate, and
a first mixture layer is provided on the first electrode in the second region, the first mixture layer being formed of a mixed material containing lead and a material forming the first electrode.

2. The liquid ejection head according to claim 1, further comprising an adhesion layer disposed between the first electrode and the piezoelectric layer in the lamination direction, wherein
the first mixture layer contains a constituent element of a material forming the adhesion layer.

3. The liquid ejection head according to claim 2, wherein
the first mixture layer contains oxide of the constituent element of the material forming the adhesion layer.

4. The liquid ejection head according to claim 1, wherein
a lead diffusion inhibition layer that inhibits diffusion of lead is provided on the first mixture layer in the lamination direction.

5. The liquid ejection head according to claim 1, wherein
a second mixture layer is provided between the first electrode and the vibration plate in the second region, the second mixture layer being formed of a mixed material containing lead and the material forming the first electrode.

6. The liquid ejection head according to claim 5, wherein
thickness of the first mixture layer is thinner than thickness of the second mixture layer.

7. The liquid ejection head according to claim 1, wherein
a third mixture layer is provided on the first electrode in the first region, the third mixture layer being formed of a mixed material containing lead and the material forming the first electrode, and
thickness of the first mixture layer is thinner than thickness of the third mixture layer.

8. The liquid ejection head according to claim 3, wherein
a third mixture layer is provided on the first electrode in the first region, the third mixture layer being formed of a mixed material containing lead and the material forming the first electrode, and
thickness of the first mixture layer is thinner than thickness of the third mixture layer.

9. The liquid ejection head according to claim 5, wherein
a third mixture layer is provided on the first electrode in the first region, the third mixture layer being formed of a mixed material containing lead and the material forming the first electrode, and
thickness of the first mixture layer is thinner than thickness of the third mixture layer.

10. The liquid ejection head according to claim 1, wherein
thickness of the first mixture layer is no less than 1/2000 and no more than ½ of thickness of the first electrode.
